(19) United States
(12) Patent Application Publication
(10) Pub. No.: US 2006/0128165 A1
(43) Pub. Date: Jun. 15, 2006

(54) Method for patterning surface modification

(75) Inventors: Steven D. Theiss, Woodbury, MN (US); Timothy D. Dunbar, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/010,846

(22) Filed: Dec. 13, 2004

(51) Int. Cl. H01L 21/42

(52) U.S. Cl. 438/795; 438/99; 438/798

(57) ABSTRACT

A method of patterning surface modification by (a) positioning a repositionable aperture mask in proximity to a substrate, and (b) selectively exposing a portion of the substrate to a surface modification treatment, wherein the exposed portion is defined by one or more apertures in the aperture mask.

### FIELD

This invention relates to methods for patterning surface modification.

### BACKGROUND

There are numerous situations in which it is desirable to change the surface properties of a film or a substrate. For example, one may wish to confine the spread of a liquid droplet to a certain area of a film by changing the surface energy, and thus the hydrophobicity/hydrophilicity, of that area of the film.

Patterning of surface energy modification can be accomplished, for example, by patterning a photoresist layer onto the film, subjecting the film to a plasma, and then removing the photoresist. The areas of the film that were exposed to the plasma will then have a different hydrophilicity than the areas that were not exposed to the plasma.

This approach can be used, for example, for patterning layers during the fabrication of thin film transistors (TFTs) by ink jet printing. Many TFT constructions require a relatively short channel length (that is, the length or distance between the source and drain electrodes in the TFT), but short channel lengths can be difficult to achieve with ink jet printing due to variations inherent to ink jet printing. Therefore, the channel is sometimes defined by photoresist patterning the areas where the source and drain are to be deposited, and then altering the surface energy of these areas with a plasma. When the photoresist is removed, the source and drain material can be ink-jetted onto the substrate. The source and drain material will be constrained to the areas previously exposed (or not exposed) to the plasma, and the channel will be defined.

### SUMMARY

In view of the foregoing, we recognize that there is a need for a simplified method for patterning surface modification.

Briefly, the present invention provides a method for patterning comprising (a) positioning a repositionable aperture mask in proximity to a substrate, and (b) selectively exposing a portion of the substrate to a surface modification treatment, wherein the exposed portion is defined by one or more apertures in the aperture mask.

As used herein, “surface modification” refers to modification of substrates by delivery of energy or particles (for example, atoms, ions, electrons, molecules, and the like) to change or improve surface characteristics (for example, adhesion properties, wettability, biocompatibility, and the like) of the material.

The method of the invention can be used to pattern surface modification on various substrates for various applications. For example, the method of the invention can be used to pattern surface modification for electronic applications (for example, TFT substrates can be patterned to define hydrophilic areas for source and drain electrodes), biomedical applications (for example, Petri dishes can be patterned to make certain areas hydrophilic and to oxidize the surface for cell attachment and growth), biotech applications (for example, surface regions of DNA microarrays/biochips can be modified to allow for attachment of DNA fragments at discrete locations), or to pattern adhesives.

The method of the invention eliminates the need to pattern photoresist on a substrate and then remove the photoresist when patterning surface modification. The method thus simplifies the patterning of surface modification.

### DETAILED DESCRIPTION

The method of the invention uses a repositionable aperture mask to pattern surface modification, which is defined by one or more apertures in the aperture mask.

The repositionable aperture mask can be formed from a polymer material such as, for example, polyimide or polyester. Polymer masks typically have a thickness of between about 5 μm and about 50 μm. In some instances, the use of polymeric materials for aperture masks can provide advantages over other materials, including ease of fabrication of the aperture mask, reduced cost of the aperture mask, and other advantages. Polymer aperture masks are flexible and are generally less prone to damage due to the accidental formation of creases or permanent bends. In addition, polymer aperture masks are generally less damaging to substrates. The use of flexible polymeric aperture masks is discussed in U.S. Pat. No. 6,821,348 (Baude et al.) and U.S. Pat. App. Pub. Nos. 03/0150384 (Baude et al.) and 03/0151118 (Baude et al.).

However, non-polymeric materials such as, for example, silicon, metals, or crystalline materials can be used for repositionable aperture masks, and are, in some instances preferable. For example, non-polymeric materials can be preferable when a light-based surface modification technique is used, or when electron beam surface modification is used (for example, to prevent charging of the mask).

The arrangement and shape of mask apertures are subject to wide variation depending upon the shape and layout of surface modification envisioned by the user. One or more apertures can be formed to have widths less than approximately 1000 μm (preferably, less than approximately 50 μm; more preferably, less than approximately 20 μm; even more preferably, less than approximately 10 μm; most preferably, less than approximately 5 μm). A distance (gap) between two apertures can be less than approximately 1000 μm (preferably, less than approximately 50 μm; more preferably, less than approximately 20 μm; most preferably, less than approximately 10 μm). When making, using, reusing, or repositioning the aperture masks, the distances between features, such as the distance between apertures or the distance between sub-patterns can be reproducible to within approximately 1.0 percent (preferably, approximately 0.5 percent, more preferably, approximately 0.1 percent).

Laser ablation techniques can be used to define the pattern of apertures in polymer aperture masks. Alternatively, if a repositionable aperture mask is formed from a silicon wafer, the pattern of apertures can be created using reactive ion etching or laser ablation. Repositionable metal aperture masks can be made by a variety of techniques including, for example, conventional machining, micromachining, diamond machining, ion beam etching, and electric discharge machining (EDM) or spark-erosion machining.

The repositionable aperture mask can be positioned in proximity to a substrate that is to be patterned with surface modification. When a surface modification technique is carried out, the exposed portion of the substrate (that is, the portion defined by the one or more apertures in the mask) will be surface modified. The unexposed portion of the substrate (that is, the portion covered by the aperture mask) will not be surface modified.

Substrates that can be surface modified include, for example, polymer films and webs, metals, glass, ceramics, semiconductors, and nonwovens. Preferably, the substrate consists of an organic material.

Surface modification techniques that are useful in the method of the invention are known in the art, and include any modification that improves or changes surface characteristics of the substrate material. The appropriate surface modification technique(s) for a given application will depend upon the type of substrate material to be modified and the type of material to be deposited on top of it, and will be apparent to one of skill in the art.

Examples of suitable surface modification techniques include flame treatment, ion beam treatment, electron beam treatment, corona treatment, plasma treatment, electrostatic discharge treatment, light treatment, exposure to reactive gases, and the like (preferably, flame treatment, ion beam treatment, electron beam treatment, corona treatment, plasma treatment, electrostatic discharge treatment, exposure to reactive gases, and the like; more preferably, flame treatment, ion beam treatment, electron beam treatment, corona treatment, plasma treatment, and the like; most preferably, plasma treatment).

Flame treatment is a method of surface modification wherein active species generated by the combustion reaction in a flame impinge on a surface (for example, a polymer surface), causing oxidation to occur. Flame treatment is particularly useful for providing wettability for water-based coatings on low surface energy polymers.

Ion beam treatment, or ion sputtering, occurs when atoms are ejected from a target due to ion bombardment. Ion beams (for example, argon-ion beams, argon/oxygen-ion beams, or krypton-ion beams), can be used, for example to clean or induce surface roughness on a polymer surface to render it more compatible with standard adhesives or to improve the adhesion of deposited films.

Electron beam (e-beam) treatment can be used to surface modify inorganic or organic materials. E-beam treatment of inorganic materials typically involves the use of concentrated electron fluxes for the surface treatment of materials. The concentrated electron flux causes rapid heating, melting, and evaporation of the surface to which the energy is delivered. When the electron flux is removed, the surface rapidly resolidifies. The rapid heating, melting, evaporation, and resolidification cause roughening of the surface. E-beam treatment of organic materials typically causes chemical reaction such as, for example, polymerization, crosslinking, chain scission, or degradation.

Corona treatments utilize an atmospheric-pressure alternating current electrical discharge to create active species in a supporting gas that modify the surface chemistry of a surface (for example, a polymer surface). Through the use of different gases in the corona, different surface chemistries can be generated. For example, air coronas lead to the oxidation of a polymer surface, nitrogen coronas cause nitrogen affixation to the polymer, nitrogen-hydrogen coronas de-fluorinate fluoropolymers, and helium-fluorocarbon coronas fluorinate surfaces.

Plasma treatment includes plasma induced grafting and surface activation, and reactive ion etching (RIE). Plasma induced grafting uses partially ionized inert gases (for example, argon, neon, krypton, or xenon) to create free radicals on a polymeric surface and generate a reactive and cross-linked surface. Plasma induced surface activation employs a reactive gas to chemically bond functional groups (for example, amine, hydroxyl, carboxyl, carbonyl, or fluorinated groups) to the surface of polymers.

Whereas most surface modification techniques render polymeric and other substrates more wettable (that is, they raise their surface energy), plasma treatment can render surfaces either hydrophobic or hydrophilic. Plasma treatment with inert gases, air, oxygen-containing gases (for example, O₂, CO, or CO₂), or nitrogen containing gases (for example, N₂, HN₃, NO₂, or NO) typically raises the surface energy of polymeric substrates, making them more hydrophilic. If the gas, however, contains a substantial atom percentage of fluorine (for example, F₂, SF₆, CF₄, C₂F₆, (CF₃)₂O, CF₃Cl, or CF₃Br), the surface energy of a polymeric substrate can be substantially lowered, making the surface hydrophobic or even oleophobic (oil repellent).

RIE involves both sputtering of a surface and chemical reaction. During RIE, the surface to be etched is bombarded with accelerated reactive ions that sputter material off the substrate, as well as react with the substrate material.

Electrostatic charge/discharge treatment can be used to either add charge to a surface or to neutralize/dissipate charge from a surface. Charge, or static electricity buildup, can cause difficulty in wetting or adhering. Electrostatic discharge treatment neutralizes the static buildup by ionizing the surrounding air. Electrically neutral atoms in air are exposed to an applied electric field of voltage to create positively and negatively charged ions. Because of the bipolar nature of the ionized air, the static charge on the material can be neutralized by the oppositely charged ions present in the surrounding air.

Light treatment includes treatment with ultraviolet (UV) light and infrared (IR) light (for example, UV or IR lasers, bulbs, or high powered arc lamps). UV light can be used, for example, to induce crosslinking in a polymer film and render exposed areas insoluble. UV light can photodegrade some polymers, however. This degradation can be avoided or minimized by using thermal irradiation/local heating with low energy IR light.

Exposure to reactive gases can effect surface modification of some substrates. For example, exposing a hydrogen-terminated silicon surface to a halogenated gas (for example, a chlorinated gas) can result in a halogen-terminated (for example, chlorine-terminated) silicon surface (see, for example, U.S. Pat. No. 6,403,382 (Zhu et al.)). The chlorine-terminated areas of the silicon surface are significantly more reactive to alcohols and amines than the hydrogen-terminated areas.

After the substrate has been selectively surface modified, a material can be deposited onto the substrate. Any material that is preferentially attracted to or repelled from the surface modified portion of the substrate versus the non-surface modified portion of the substrate can be used. Preferably, the material is a liquid or a powder.

The material can be deposited by any useful means. Depending upon the material, useful means can include vapor deposition (for example, physical or chemical vapor deposition), liquid deposition (for example, spin coating, dip coating, meniscus coating, gravure coating, or printing techniques such as ink jet printing, flexographic printing, and the like), or powder deposition.

The method of the invention is particularly useful in the fabrication of various electronic devices, TFTs, and ICs. TFTs generally include a gate electrode, a gate dielectric on the gate electrode, a source electrode and a drain electrode adjacent to the gate dielectric, and a semiconductor layer adjacent to the gate dielectric and adjacent to the source and drain electrodes. These components, or features, are typically provided on a substrate, and can be assembled in a variety of configurations. For example, the source and drain electrodes can be adjacent to the gate dielectric with the semiconductor layer over the source and drain electrodes, or the semiconductor layer can be interposed between the source and drain electrodes and the gate dielectric. The method of the invention can be used to pattern any one or more of these features.

For example, the method of the invention can be used to selectively pattern surface modification on a TFT substrate in the areas where the source and drain electrodes are to be located. Then, when the source and drain electrodes are deposited onto the substrate, they will be confined to the surface modified areas. It is possible to obtain a precisely defined channel between the source and drain electrodes that is between about 5 μm and about 50 μm (preferably, between about 5 μm and about 20 μm; more preferably, between about 5 μm and about 10 μm).

A TFT substrate typically supports a TFT during manufacturing, testing, and/or use. Substrate materials include organic and inorganic materials. For example, the substrate can comprise inorganic glasses, ceramic foils, polymeric materials (for example, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(phenylene sulfide) (PPS)), filled polymeric materials (for example, fiber-reinforced plastics (FRP)), fibrous materials, such as paper and textiles, and coated or uncoated metallic foils. TFT substrates can be flat and/or rigid or flexible. A flexible substrate allows for roll processing, which may be continuous, providing economy of scale and economy of manufacturing over flat and/or rigid substrates.

Inorganic glass and ceramic foil TFT substrates can be surfaced modified, for example, using hydrogen fluoride (HF) vapor or electrostatic charge treatment. Polymeric TFT substrates can be surfaced modified, for example, using plasma treatment.

A material that forms the source and drain electrodes can then be deposited onto the TFT substrate. The source and drain electrodes can be any useful conductive material that is preferentially attracted to or repelled from the surface modified portion of the TFT substrate versus the non-surface modified portion of the TFT substrate. For example, the source and drain electrodes can comprise conductive inks, or conductive polymers such as polyaniline or poly(3,4-ethylenedioxythiophene)/poly(styrene sulfonate) (PEDOT:PSS).

The method of the invention can also be used, for example, to selectively pattern surface modification on a gate dielectric in the areas where a semiconductor is to be located. Then, when the semiconductor material is deposited onto the gate dielectric, it will be confined to the surface modified areas. Surface modification can also, in some instances, provide an improved interface between the gate dielectric and an organic semiconductor.

The gate dielectric is generally provided on the gate electrode. The gate dielectric electrically insulates the gate electrode from the balance of the TFT device. It can be deposited on the TFT as a separate layer, or formed on the gate by oxidizing (including anodizing) the gate material to form the gate dielectric. The gate dielectric preferably has a relative dielectric constant above about 2 (more preferably, above about 5). The dielectric constant of the gate dielectric can be relatively high, for example, 80 to 100 or higher. Useful materials for the gate dielectric can comprise, for example, organic or inorganic electrically insulating materials.

Specific examples of organic insulating materials useful for the gate dielectric include polymeric materials, such as polyvinylidenefluoride (PVDF), cyanocelluloses, polyimides, epoxies, and the like.

Other useful organic insulating materials are described in copending application U.S. Ser. No. 10/434377, filed on May 8, 2003, which is herein incorporated by reference. These materials include cyano-functional (preferably, cyano-functional styrenic) polymers, preferably with relatively high dielectric constants. Suitable polymers preferably include a cyano-functional portion and a portion that provides a relatively high dielectric constant to the overall polymer, which portions may be the same or different.

Specific examples of inorganic insulating materials useful for the gate dielectric include strontiates, tantalates, titanates, zirconates, aluminum oxides, silicon oxides, tantalum oxides, titanium oxides, hafnium oxides, silicon nitrides, barium titanate, barium strontium titanate, and barium zirconate titanate. In addition, alloys, combinations, and multilayers of these materials can be used for the gate dielectric.

Preferred inorganic insulating materials for the gate dielectric include aluminum oxides, silicon oxides, and silicon nitrides.

Organic insulating materials can be surface modified, for example, using plasma treatment. Inorganic insulating materials can be surface modified, for example, using electrostatic charge treatment or HF vapor.

After the gate dielectric has been surface modified, a semiconductor material can be deposited onto the gate dielectric. The semiconductor material can be any useful semiconductor material that is preferentially attracted to or repelled from the surface modified portion of the gate dielectric versus the non-surface modified portion of the gate dielectric. The semiconductor material can be organic or inorganic.

For deposition of organic semiconductor materials from solutions or organic liquids, plasma treatment with fluorinated gases can be particularly useful. Many organic liquids have surface energies (surface tensions) significantly lower than that of water. Furthermore, some substrates can be substantially hydrophilic in their clean state. As a result, organic liquids might not be confined to particular regions by the surface energy difference between treated and untreated areas of polymer substrates if the surface modification technique that was used is one that increases surface energy (that is, makes a surface more hydrophilic). Plasma treatment with fluorinated gases, which render a substrate's surface energy so low as to make them oleophobic, can therefore be useful for repelling organic liquids from the treated regions.

Furthermore, even greater contrast in surface energies between substrate regions can be obtained using a combination of surface modification techniques. For example, one surface modification technique can be used to reduce surface energy in one region and another surface modification technique can be used to increase surface energy in another region. This can be accomplished by using an aperture mask to selectively pattern surface modification to increase the surface energy of a region defined by the mask aperture(s), and then using a second aperture mask to selectively pattern surface modification to decrease the surface energy of second region defined by the apertures of the second mask. Alternatively, the same mask can be moved to a second region of the substrate.

Useful inorganic semiconductor materials include amorphous and poly silicon, tellurium, zinc oxide, zinc selenide, zinc sulfide, cadmium sulfide, and cadmium selenide.

Useful organic semiconductor materials include acenes and substituted derivatives thereof. Particular examples of acenes include anthracene, naphthalene, tetracene, pentacene, and substituted pentacenes (preferably pentacene or substituted pentacenes). Other examples include semiconducting polymers, perylenes, fullerenes, phthalocyanines, oligothiophenes, polythiophenes, polyphenylvinylenes, polyacetylenes, metallophthalocyanines and substituted derivatives. Useful bis-(2-acenyl) acetylene semiconductor materials are described in copending application U.S. Ser. No. 10/620027, filed on Jul. 15, 2003, which is herein incorporated by reference. Useful acene-thiophene semiconductor materials are described in copending application U.S. Ser. No. 10/641730, filed on Aug. 15, 2003, which is herein incorporated by reference.

Substituted derivatives of acenes include acenes substituted with at least one electron-donating group, halogen atom, or a combination thereof, or a benzo-annellated acene or polybenzo-annellated acene, which optionally is substituted with at least one electron-donating group, halogen atom, or a combination thereof. The electron-donating group is selected from an alkyl, alkoxy, or thioalkoxy group having from 1 to 24 carbon atoms. Preferred examples of alkyl groups are methyl, ethyl, n-propyl, isopropyl, n-butyl, sec-butyl, n-pentyl, n-hexyl, n-heptyl, 2-methylhexyl, 2-ethylhexyl, n-octyl, n-nonyl, n-decyl, n-dodecyl, n-octadecyl, and 3,5,5-trimethylhexyl. Substituted pentacenes and methods of making them are taught in U.S. Patent App. Pub. Nos. 03/0100779 (Vogel et al.) and 03/0105365 (Smith et al.), which are herein incorporated by reference.

Further details of benzo-annellated and polybenzo-annellated acenes can be found in the art, for example, in National Institute of Standards and Technology (NIST) Special Publication 922 “Polycyclic Aromatic Hydrocarbon Structure Index”, U.S. Govt. Printing Office, by Sander and Wise (1997).

Useful trans-1,2-bis(acenyl)ethylene semiconductor compounds are described in copending application U.S. Ser. No. 10/991563, filed on Nov. 18, 2004, which is herein incorporated by reference.

The method of the invention can also be used, for example, to selectively pattern surface modification on a gate dielectric in the areas where a gate electrode is to be located. Then, when the gate electrode material is deposited onto the gate dielectric, it will be confined to the surface modified areas.

After the gate dielectric has been surface modified using one of the surface modification techniques discussed above, a gate material can be deposited onto the gate dielectric. The gate electrode material can be any useful conductive material that is preferentially attracted to or repelled from the surface modified portion of the gate dielectric versus the non-surface modified portion of the gate dielectric. For example, the gate electrode can be formed from conductive inks, or conductive polymers such as polyaniline or poly(3,4-ethylenedioxythiophene)/poly(styrene sulfonate) (PEDOT:PSS).

Similarly, as will be apparent to one of skill in the art, other TFT layers or feature, including optional layers such as surface treatment layers or sealing layers, can be patterned using the described method of patterning surface modification. Useful surface treatment layers are described, for example, in U.S. Patent Application Publication No. 03/0102471 (Kelley et al.), and U.S. Pat. No. 6,433,359 (Kelley et al.) and U.S. Pat. No. 6,617,609 (Kelley et al.). Useful sealing layers are described, for example, in U.S. Ser. No. 10/642919, filed on Aug. 18, 2003. Again, appropriate surface modification techniques will depend upon the material of the surface to be modified and the material of the TFT layer or feature to be deposited on top of the surface.

The patterning method of the invention can also be used to pattern surface modification on a previously surface modified substrate. For example, an entire substrate can be surface modified to make the substrate oleophobic, and then the patterning method of the invention can be used to selectively surface modify a region of the substrate to be hydrophilic.

The referenced descriptions contained in the patents, patent documents, and publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

We claim:

1. A patterning method comprising (a) positioning a repositionable aperture mask in proximity to a substrate, and (b) selectively exposing a portion of the substrate to a surface modification treatment, wherein the exposed portion is defined by one or more apertures in the aperture mask.

2. The method of claim 1 wherein the surface modification treatment modifies the surface energy of the exposed portion of the substrate.

3. The method of claim 1 wherein the surface modification treatment is selected from the group consisting of flame treatment, ion beam treatment, electron beam treatment, corona treatment, plasma treatment, electrostatic discharge treatment, light treatment, and exposure to reactive gases.

4. The method of claim 3 wherein the surface modification treatment is selected from the group consisting of flame treatment, ion beam treatment, electron beam treatment, corona treatment, plasma treatment, electrostatic discharge treatment, and exposure to reactive gases.

5. The method of claim 4 wherein the surface modification technique is plasma treatment.

6. The method of claim 1 wherein the substrate consists of a polymeric material.

7. The method of claim 6 wherein the surface modification technique is plasma treatment, and the plasma treatment increases the surface energy of the exposed portion.

8. The method of claim 6 wherein the surface modification technique is plasma treatment, and the plasma treatment decreases the surface energy of the exposed portion.

9. The method of claim 1 further comprising positioning a second repositionable aperture mask in proximity to the substrate, and selectively exposing a second portion of the substrate to a second surface modification technique, wherein the second exposed portion is defined by one or more apertures in the second aperture mask.

10. The method of claim 9 wherein one of the surface modification techniques increases the surface energy of the substrate and the other surface modification technique decreases the surface energy of the substrate.

11. The method of claim 1 wherein the aperture mask is a polymeric aperture mask.

12. The method of claim 1 wherein one or more apertures in the aperture mask have a width less than approximately 50 μm.

13. The method of claim 1 wherein the exposed portion defines a feature of a thin film transistor or a portion of an integrated circuit.

14. The method of claim 13 wherein the exposed portion defines source and drain electrodes.

15. The method of claim 14 wherein the channel length between the source and drain electrodes is less than about 10 μm.

16. The method of claim 1 further comprising depositing a material onto the substrate, the pattern of the resulting material layer being influenced by the surface modification of portions of the substrate.

17. The method of claim 16 wherein the material is an organic material.

18. The method of claim 16 wherein the material is deposited by a liquid deposition technique.

19. The method of claim 18 wherein the liquid deposition technique is ink jet printing.

20. The method of claim 16 wherein the material forms source and drain electrodes.

21. The method of claim 16 wherein the material is a semiconductor material.

22. The method of claim 21 wherein the semiconductor material is an organic semiconductor material.

23. The method of claim 16 wherein the material is a conducting material.

24. The method of claim 16 wherein the material is an insulating material.
